(19) United States
(12) Patent Application Publication
(10) Pub. No.: US 2018/0358443 A1
(43) Pub. Date: Dec. 13, 2018

(54) SILICON CARBIDE WAFER AND POSITIONING EDGE PROCESSING METHOD THEREOF

(71) Applicant: GlobalWafers Co., Ltd., Hsinchu (TW)

(72) Inventors: Chan-Ju Wen, Hsinchu (TW); Wei-Kuo Huang, Hsinchu (TW); I-Ching Li, Hsinchu (TW); Chi-Hsiang Hsieh, Hsinchu (TW)

(73) Assignee: GlobalWafers Co., Ltd., Hsinchu (TW)

(21) Appl. No.: 15/856,074

(22) Filed: Dec. 28, 2017

(30) Foreign Application Priority Data
Jun. 8, 2017 (TW) 106118979

(51) Int. Cl. H01L 29/16; H01L 21/02; H01L 23/544; H01L 21/66; H01L 21/04

(52) U.S. Cl. CPC H01L 29/1608; H01L 21/02021; H01L 2223/54493; H01L 22/20; H01L 21/0475; H01L 23/544

(57) ABSTRACT

A silicon carbide (SiC) wafer and a positioning-edge processing method thereof are provided. The SiC wafer has a first flat and a second flat. A first rounded corner is respectively disposed at a connection between two ends of the first flat and an edge of the SiC wafer, wherein the first rounded corner has a radius of 1-10 mm. A second rounded corner is respectively disposed at a connection between two ends of the second flat and the edge of the SiC wafer, wherein the second rounded corner has a radius of 1-10 mm. Since the rounded corners at the connections between two ends of the flats and the wafer edges have optimum radii, the yield and quality of the wafer processing may be improved.

### CROSS-REFERENCE TO RELATED APPLICATION

This application claims the priority benefit of Taiwan application serial no. 106118979, filed on Jun. 8, 2017. The entirety of the above-mentioned patent application is hereby incorporated by reference herein and made a part of this specification.

### BACKGROUND

### Field of the Invention

The invention relates to a processing technology of silicon carbide (SiC) wafers and more particularly, to a positioning edge processing method of SiC wafers.

### Description of Related Art

Comparing with conventional semiconductor silicon wafers, since silicon carbide (SiC) wafers have a wider band gap and higher thermal stability, the SiC wafers have been widely used in electronic components of high temperature, high pressure, high frequency, high power and photoelectric applications.

However, the hardness of the SiC wafers is high. Therefore, it is not easy to process on the connections of the flats of the SiC wafers and the wafer edges. Thus, stress concentration problems may occur on the connections of the flats and the wafer edges. The SiC wafers are easily broken when the SiC wafers are transported or packed in boxes, and the yield of the SiC wafers cannot be increased.

### SUMMARY

The invention provides a SiC wafer to decrease the stress on two ends of the flats of the SiC wafers.

The invention further provides a positioning-edge processing method to increase the yield of the SiC wafers.

One of the present inventions comprises a SiC wafer having a first flat and a second flat. In the SiC wafer, a first rounded corner is disposed at a connection between one end of the first flat and an edge of the SiC wafer and between another end of the first flat and the edge of the SiC wafer, and a second rounded corner is disposed at a connection between one end of the second flat and the edge of the SiC wafer and between another end of the second flat and the edge of the SiC wafer. The first rounded corner has a radius of 1-10 mm, and the second rounded corner has a radius of 1-10 mm.

In one embodiment, the radius of the first rounded corner is equal to the radius of the second rounded corner.

In one embodiment, the radius of the first rounded corner is larger than the radius of the second rounded corner.

In one embodiment, a width of the first flat is larger than a width of the second flat.

In one embodiment, the first flat is disposed at 90° to the second flat.

In one embodiment, a diameter of the SiC wafer is 50-200 mm.

Another of the present inventions comprises a positioning-edge processing method of a silicon carbide (SiC) wafer. In the method, the original specification of the SiC wafer is inspected to obtain a diameter WD of the SiC wafer, a diameter OD1 at a first flat of the SiC wafer, and a diameter OD2 at a second flat of the SiC wafer. Then, the processing number is assessed when the diameter WD of the SiC wafer, the diameter OD1 at the first flat, and the diameter OD2 at the second flat are larger than or equal to corresponding first spec values. According to the assessed processing number, a multi-stage feeding is performed on the SiC wafer to form a first rounded corner respectively disposed at connections between two ends of the first flat and an edge of the SiC wafer and to form a second rounded corner respectively disposed at connections between two ends of the second flat and the edge of the SiC wafer. After the multi-stage feeding, the SiC wafer is inspected to obtain values of the diameter WD of the SiC wafer, the diameter OD1 at the first flat, the diameter OD2 at the second flat, a width OF1 of the first flat, a width OF2 of the second flat, a radius r1 of the first rounded corner, and a radius r2 of the second rounded corner. The SiC wafer processing is finished when the diameter WD of the SiC wafer, the diameter OD1 at the first flat, and the diameter OD2 at the second flat are greater than or equal to corresponding second spec values.

In an embodiment, the SiC wafer is replaced when the diameter WD of the SiC wafer, the diameter OD1 at the first flat, and the diameter OD2 at the second flat are smaller than the corresponding first spec values.

In another embodiment, the SiC wafer is replaced when the diameter WD of the SiC wafer, the diameter OD1 at the first flat, and the diameter OD2 at the second flat are smaller than the corresponding second spec values.

Accordingly, in the present invention, rounded corners having optimum radius are disposed on connections of the two ends of the flats and wafer edges, and thus the stress of the connections can be reduced. Hence, the SiC wafers will not be easily broken during transportation and packed in boxes to increase the yield of the SiC wafers.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a diagram showing a SiC wafer according to an embodiment of this invention.

FIG. 2 is a flow diagram illustrating the positioning-edge processing of a SiC wafer according to another embodiment of this invention.

FIG. 3 is a bar chart showing the yields of an example and a comparative example.

### DESCRIPTION OF THE EMBODIMENTS

The embodiments of this inventions, with figures, will be detailed described below. However, these embodiments are only illustrative, and this invention is not limited thereto. The common features of the using methods, structures, and/or materials shown in figures are supplementary to the literal description. For example, the relative sizes and positions of regions and/or structures may be reduced or enlarged for the reason of making a clear illustration.

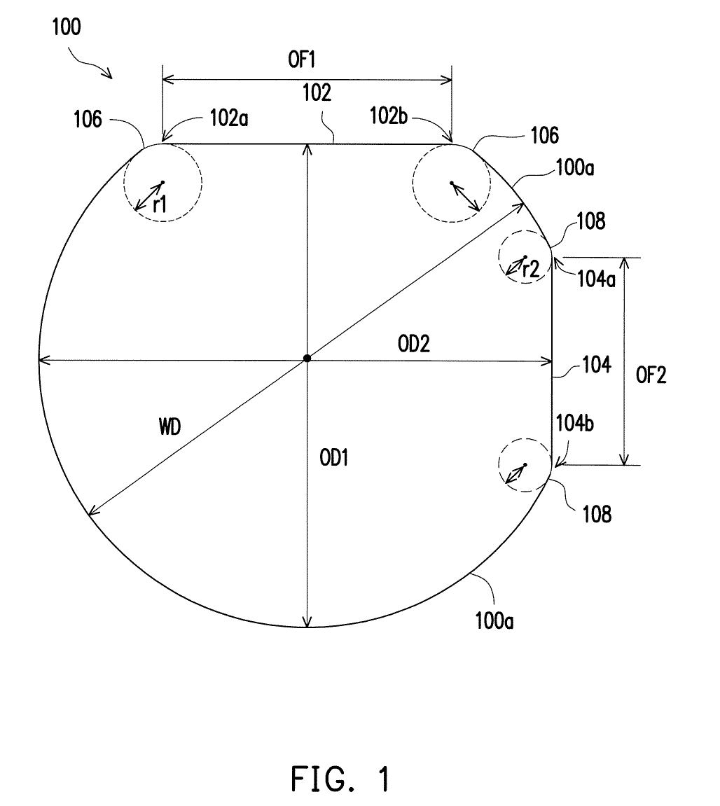

FIG. 1 is a diagram showing a SiC wafer according to an embodiment of this invention. In FIG. 1, the SiC wafer 100 has a first flat 102 and a second flat 104. The first flat 102 may be a primary flat, and the second flat 104 may be a secondary flat, but this invention is not limited thereto. A first rounded corner (also referred to as “R angle”) 106 is respectively disposed on connections of two ends 102a and 102b of the first flat 102 and wafer edge 100a being adjacent thereto, and the first rounded corner has a radius r1 of 1-10 mm. A second rounded corner 108 is respectively disposed on connections of two ends 104a and 104b of the second flat 104 and the wafer edge 100a being adjacent thereto, and the second rounded corner 108 has a radius r2 of 1-10 mm. According to the different sizes of the SiC wafers, the ranges of the radius r1 and the radius r2 may be slightly varied. Please see Table 1 below.

TABLE 1

| | | | | r2 of the | |
|---|---|---|---|---|---|
| | | | | second rounded | |
| | | r1 of the first rounded | | corner | |
| SiC wafer | | corner | | | Lower |
| Sizes | Diameter | Upper limit | Lower limit | Upper limit | limit |
| (inch) | (mm) | (mm) | (mm) | (mm) | (mm) |
| 3 | 75 | 3 | 2 | 3 | 2 |
| 4 | 100 | 5 | 4 | 5 | 4 |

In an embodiment of this invention, the radius r1 of the first rounded corner may be equal to or larger than the radius r2 of the second rounded corner. The width OF1 of the first flat 102 is larger than the width OF2 of the second flat 104. In here, the term “OF” is the abbreviation of “orientation flat.” The first flat 102 may be disposed at 90° to the second flat 104. That is, the extending lines of the first flat 102 and the second flat 104 may form an angle of 90°. In addition, the r WD of the

SiC wafer 100 is, for example, 50-200 mm and can be adjusted according to the requirements.

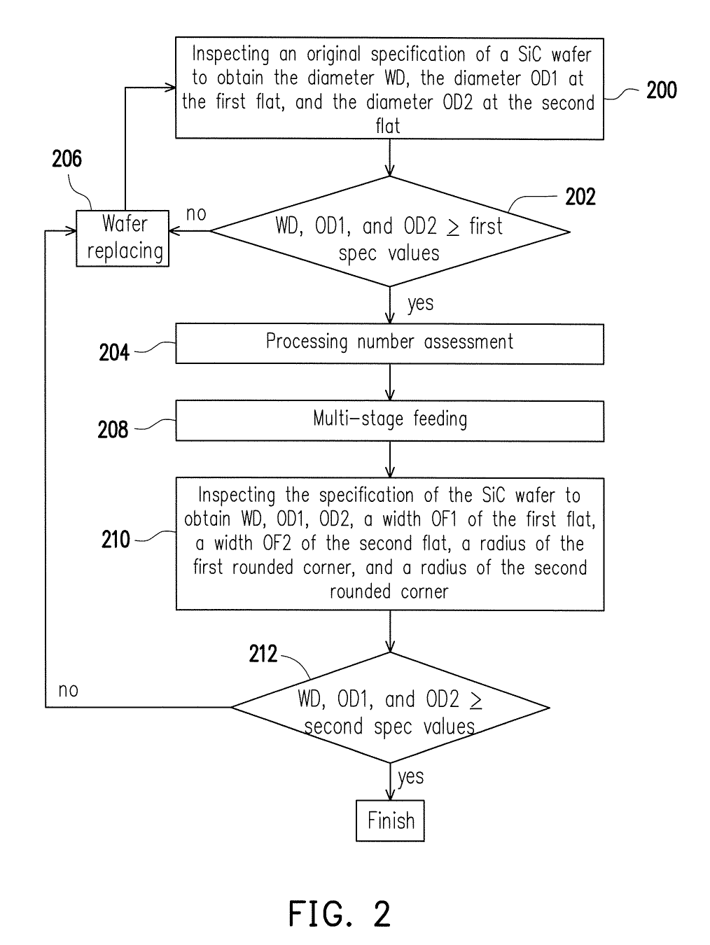

FIG. 2 is a flow diagram illustrating the positioning-edge processing of the SiC wafer according to another embodiment of this invention. The abbreviations in FIG. 2 may be referred to those shown in FIG. 1.

In FIG. 2, step 200 is performed to inspect an original specification of a SiC wafer to obtain the diameter WD of the SiC wafer, the diameter OD1 at the first flat of the SiC wafer, and the diameter OD2 at the second flat of the SiC wafer.

Next, in step 202, it is confirmed whether the diameter WD of the SiC wafer, the diameter OD1 at the first flat and the diameter OD2 at the second flat are greater than corresponding first spec values. The so-called “first spec values” are predetermined values corresponding to the WD, OD1 and OD2. Therefore, the first spec values have several different values, not only a single value.

When the diameter WD of the SiC wafer, the diameter OD1 at the first flat and the diameter OD2 at the second flat are greater than or equal to the t spec values, step 204 (processing number assessment) is performed. Since the hardness of the SiC wafer is high, processing in a multi-stage feeding mode is adapted to avoid from damaging the SiC wafer. Comparing the original spec values obtained in step 200 and the first spec values, the processing capacity can be obtained by this assessment. The processing number can be further obtained from the processing capacity. For example, the processing number may be 2 to 10, but this invention is not limited thereto.

However, when the diameter WD of the SiC wafer, the diameter OD1 at the first flat, and the diameter OD2 at the second flat are smaller than the first spec values, the SiC wafer cannot be processed anymore. Therefore, the SiC wafer will be replaced by a new SiC wafer (step 206) to perform the positioning-edge processing.

After step 204, a step 208 of multi-stage feeding is preformed on the SiC wafer according to the assessed processing number, so that a first rounded corner is respectively formed at connections between two ends of the first flat and an edge of the SiC wafer, and a second rounded corner is respectively formed at connections between two ends of the second flat and the edge of the SiC wafer. The multi-stage feeding, for example, includes several coarse grindings and one fine grinding. For example, if the assessed processing number is five, the multi-stage feeding includes four coarse grindings and one fine grinding, and the number (particle size) of the grinding wheel is #300 to #3000, for example.

After finishing step 208, a step 210 is performed. The processed SiC wafer is inspected to obtain values of the diameter WD of the SiC wafer, the diameter OD1 at the first flat, a width OF1 of the first flat, the diameter OD2 at the second flat, a width OF2 of the second flat, a radius r1 of the first rounded corner, and a radius r2 of the second rounded corner.

Then, a step 212 is performed. It is confirmed whether the diameter WD of the SiC wafer, the diameter OD1 at the first flat, and the diameter OD2 at the second flat is greater than or equal to corresponding second spec values. The so-called “second spec values” are predetermined values of WD, OD1 and OD2. The corresponding second spec values may be different from the corresponding first spec values, and include several different values.

When the diameter WD of the SiC wafer, the diameter OD1 at the first flat, and the diameter OD2 at the second flat are smaller than the corresponding second spec values, the SiC wafer is replaced (step 206). On the contrary, when the diameter WD of the SiC wafer, the diameter OD1 at the first flat, and the diameter OD2 at the second flat are larger than or equal to corresponding second spec values, the positioning-edge processing of the SiC wafer is finished.

Experiments are made to prove the effect of this invention is not limited thereto.

### EXAMPLE

Four-inch SiC wafers were used. The SiC wafer has a first flat and a second flat. The first spec values include WD: 100.1±0.05, OD1: 97.4±0.05, and OD2: 99.3±0.05. The second spec values include WD:100±0.05, OD1: 97.3±0.05, and OD2: 99.2∓0.05.

The positioning-edge processing was performed according to FIG. 2 to make the SiC wafers have first rounded corner and second corner with radii in optimum ranges.

### COMPARATIVE EXAMPLES

Four-inch SiC wafers having a first flat and a second flat were used, but the SiC wafers were not processed by the positioning-edge processing of the examples.

### <Yield>

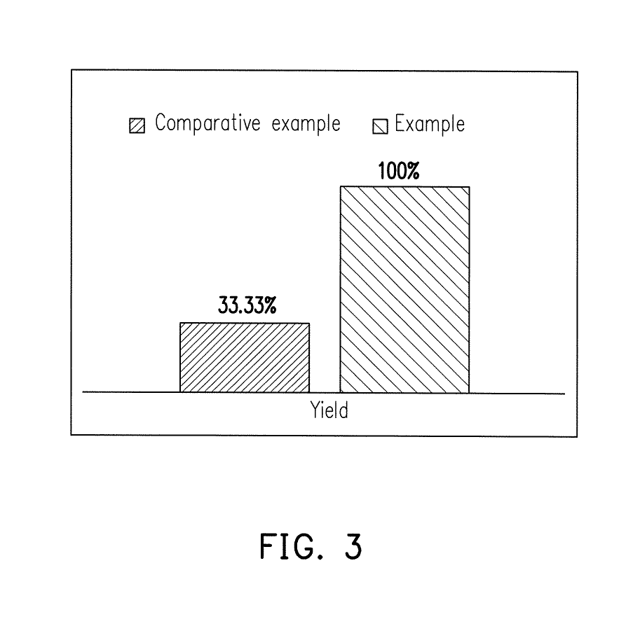

Edge-rounding was performed on the 40 pieces of SiC wafers of the examples and the comparative examples to remove the microcracks on the edges of the wafers. An optical microscope (OM) was used to inspect the SiC wafers for checking whether the SiC wafers are broken or not. The results are shown in FIG. 3. The spec of the chamfers can be inspected by checking the projections of the chamfers by an edge profile instrument. In FIG. 3, the SiC wafers of the examples were not broken at all, and the yield was 100%. However, the yield of the comparative examples was only 33.33%.

Accordingly, the connections of the two ends of the flats of the SiC wafers and the adjacent wafer edges thereof have rounded corners with radii in optimum ranges to avoid wafers from being broken during the transportation or being packed in boxes. The effect of increasing the yield and quality of SiC wafers is achieved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

1. A silicon carbide (SiC) wafer having a first flat and a second flat, wherein:
a first rounded corner, disposed at a connection between one end of the first flat and an edge of the SiC wafer and between another end of the first flat and the edge of the SiC wafer, wherein the first rounded corner has a radius of 1-10 mm; and
a second rounded corner, disposed at a connection between one end of the second flat and the edge of the SiC wafer and between another end of the second flat and the edge of the SiC wafer, wherein the second rounded corner has a radius of 1-10 mm.

2. The silicon carbide wafer of claim 1, wherein the radius of the first rounded corner is equal to the radius of the second rounded corner.

3. The silicon carbide wafer of claim 1, wherein the radius of the first rounded corner is larger than the radius of the second rounded corner.

4. The silicon carbide wafer of claim 1, wherein a width of the first flat is larger than a width of the second flat.

5. The silicon carbide wafer of claim 1, wherein the first flat is disposed at 90° to the second flat.

6. The silicon carbide wafer of claim 1, wherein a diameter of the SiC wafer is 50-200 mm.

7. A positioning-edge processing method of a silicon carbide (SiC) wafer, comprising:
inspecting an original specification of the SiC wafer to obtain a diameter of a SiC wafer, a diameter of a first flat at the SiC wafer, and a diameter at a second flat of the SiC wafer;
assessing a processing number when the diameter of the SiC wafer, the diameter at the first flat, and the diameter at the second flat are larger than or equal to first spec values;
performing a multi-stage feeding on the SiC wafer according to the assessed processing number so as to form a first rounded corner respectively disposed at connections between two ends of the first flat and an edge of the SiC wafer and to form a second rounded corner respectively disposed at connections between two ends of the second flat and the edge of the SiC wafer;
inspecting the SiC wafer after the multi-stage feeding to obtain values of the diameter of the SiC wafer, the diameter at the first flat, a width of the first flat, the diameter at the second flat, a width of the second flat, a radius of the first rounded corner, and a radius of the second rounded corner; and
finishing the processing when the diameter of the SiC wafer, the diameter at the first flat, and the diameter at the second flat are greater than or equal to second spec values.

8. The method of claim 7, further comprising replacing the SiC wafer when the diameter of the SiC wafer, the diameter at the first flat, and the diameter at the second flat are smaller than the first spec values.

9. The method of claim 7, further comprising replacing the SiC wafer when the diameter of the SiC wafer, the diameter at the first flat, and the diameter at the second flat are smaller than the second spec values.
